(19) United States
(12) Patent Application Publication
(10) Pub. No.: US 2012/0055704 A1
(43) Pub. Date: Mar. 8, 2012

(54) EPOXY RESIN BLEND

(75) Inventors: Tsung Fan TSENG, Hsinchu County (TW); Tsung Hsein LIN, Hsinchu County (TW); Hsien Te CHEN, Hsinchu County (TW); Hsuan Hao HSU, Hsinchu County (TW); Chih Wei LIAO, Hsinchu County (TW)

(73) Assignee: TAIWAN UNION TECHNOLOGY CORPORATION, Hsinchu County (TW)

(21) Appl. No.: 12/876,201

(22) Filed: Sep. 6, 2010

(51) Int. Cl. H05K 1/00; B32B 5/16; B32B 27/04; C01B 33/24

(52) U.S. Cl. 174/258; 423/331; 428/402; 428/375; 428/297.4

(57) ABSTRACT

Embodiments of the present disclosure set forth a sintered talc powder. The sintered talc powder comprising a first X-ray diffraction peak from about 29° to about 30° and having a first intensity and a second X-ray diffraction peak from about 25° to about 27° and having a second intensity, wherein the first intensity is greater than the second intensity.

### BACKGROUND OF THE DISCLOSURE

Epoxy resin blends have many applications. For example, an epoxy resin blend can be applied on a fibrous material to form a prepreg for making a copper clad laminate of a printed circuit board. Such epoxy resin blend may include an epoxy compound, a crosslinking agent, a catalyst, and a filler. The filler may include talc powder. Talc powder that is sintered at high temperatures typically produces a product with a hardness that makes subsequent processing of the prepreg/copper clad laminate difficult. However, non-sintered talc powder may include impurities, which makes the properties of the prepreg/copper clad laminate unstable. There is a need for an improved method for producing sintered talc powder of suitable hardness for inclusion in an epoxy resin for production of a circuit board.

### SUMMARY OF THE DISCLOSURE

Embodiments of the disclosure set forth a sintered talc powder. The sintered talc powder includes a first X-ray diffraction peak from about 29° to about 30° at a first intensity and a second X-ray diffraction peak from about 25° to about 27° at a second intensity, wherein the first intensity is greater than the second intensity.

Embodiments of the disclosure set forth a method for making talc powder. The method includes preheating the talc powder; sintering the talc powder, after the preheating and; and annealing the talc powder, after the sintering.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is an X-ray powder diffraction chart for talc powder that has been sintered at a temperature of about 1,050 degrees Celsius in accordance with a method as described herein.

FIG. 2 is an X-ray powder diffraction chart for talc powder that has been sintered at a temperature of about 1,100 degrees Celsius in accordance with a method as described herein.

FIG. 3 is an X-ray powder diffraction chart for talc powder that has been sintered at a temperature of about 1,100 degrees Celsius in accordance with a conventional method.

FIG. 4 is an X-ray powder diffraction chart for talc powder that has been sintered at a temperature of about 1,200 degrees Celsius in accordance with a conventional method.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure.

In the disclosure, a “prepreg” generally refers to a material which includes or is impregnated with an amount of resin before a molding operation. A “copper clad laminate” generally refers to a laminate which includes copper (e.g., copper sheet or copper foil) and a prepreg. “Talc” generally refers to a mineral compound of hydrated magnesium silicate with a chemical formula 3MgO.4SiO₂.H₂O. In loose form, talc is a widely-used substance known as talcum powder. “Annealing” or “annealed” generally refers to a process that includes heating a material to a suitable temperature to provide energy for the diffusion of the atoms within the material, and then cooling the material to the room temperature at a relatively slow rate so that the material is altered, causing changes of the properties of the material.

This disclosure is drawn, inter alia, to an epoxy resin blend which includes talc powder, and applications of use related to the epoxy resin blend.

In some embodiments, the epoxy resin blend described herein includes an epoxy compound, a crosslinking agent, a catalyst, and a filler. An epoxy compound broadly refers to a chemical substance, which generally includes a three-member ring known as an epoxy, epoxide, oxirane, or ethoxyline group. In some embodiments, the epoxy compound may include brominated and/or phosphonated epoxy compounds, so that the epoxy resin blend can be flame retardant. Generally, the epoxy compound may include, without limitation, an aromatic epoxy compound, an alicyclic epoxy compound, and/or an aliphatic epoxy compound.

Examples of the aromatic epoxy compounds may include glycidyl ethers of polyhydric phenols, such as hydroquinone, resorcinol, bisphenol A, bisphenol F, 4,4′-dihydroxybiphenyl, novolak, and tetrabromobisphenol A.

Examples of the alicyclic epoxy compounds may include hydrogenated bisphenol A diglycidyl ether, (3,4-epoxycyclohexyl)methyl 3,4-epoxycyclohexylcarboxylate, 3,4-epoxy-1-methylcyclohexyl 3,4-epoxy-1-methylhexanecarboxylate, (6-methyl-3,4-epoxycyclohexyl)methyl 6-methyl-3,4-epoxycyclohexanecarboxylate, (3,4-epoxy-3-methylcyclohexyl)methyl 3,4-epoxy-3-methylcyclohexanecarboxylate, (3,4-epoxy-5-methylcyclohexyl)methyl 3,4-epoxy-5-methylcyclohexanecarboxylate, bis(3,4-epoxycyclohexylmethyl)adipate, methylenebis(3,4-epoxycyclohexane), 2,2-bis(3,4-epoxycyclohexyl)propane, dicyclopentadiene diepoxide, ethylenebis(3,4-epoxyyclohexanecarboxylate), dioctyl epoxyhexahydrophthalate, and di-2-ethylhexyl epoxyhexahydrophthalate.

Examples of the aliphatic epoxy compounds may include glycidyl ethers of polyhydric alcohols, such as 1,4-butanediol diglycidyl ether, 1,6-hexanediol diglycidyl ether, glycerol triglycidyl ether, trimethylolpropane triglycidyl ether, sorbitol tetraglycidyl ether, dipentaerythritol hexaglycidyl ether, polyethylene glycol diglycidyl ether, and polypropylene glycol diglycidyl ether; polyether polyol polyglycidyl ethers obtained by adding one or more alkylene oxides to aliphatic polyhydric alcohols, such as propylene glycol, trimethylolpropane, and glycerol; and diglycidyl esters of aliphatic long-chain dibasic acids.

Any crosslinking agent that may serve the function of forming a network based on compounds or polymers may be used for crosslinking the epoxy compound in the epoxy resin blend described herein. A crosslinking agent may include, without limitation, derivatives of acrylate and methacrylate. For example, the crosslinking agent can be styrene maleic anhydride (SMA) copolymer. SMA copolymer is commercially available in a broad range of molecular weights and monomer weight ratios. Typically, the molecular weight of SMA copolymer may vary from approximately 1,400 daltons to approximately 14,000 daltons (weight average molecular weight), and the weight ratio of styrene monomer to maleic anhydride may range from approximately 1:1 to approximately 10:1.

In some embodiments, a crosslinking agent may include a phenol-formaldehyde resin. Examples of the phenol-formaldehyde resin may include novolac and resol.

Any catalyst that may serve the function of accelerating a reaction rate may be used for accelerating the crosslinking rate of the epoxy resin blend described herein. A catalyst may be organic. An organic catalyst may include 2-methylimidazole and 2-ethyl-4-methylimidazole.

The epoxy resin blend described herein contains a filler that includes talc. In some embodiments, the filler may also include other compounds, such as, for example, aluminum trihydrate, mica, and/or kaolin.

A method is provided herein for treatment of talc before it is included in the epoxy resin blend. The treatment includes preparing talc powder, preheating the talc powder, sintering the talc powder and annealing the talc powder.

In the preparing step, it may further include removing impurities from the surface of talc in its natural form, and grinding the talc with a mill to break it into talc powder. The talc powder may have particle diameters less than about 200 μm. The particle diameters of about 50 percent of the talc powder are about 0.5 μm to about 50 μm.

In the preheating step, the talc powder is heated in an oven at a temperature of about 600 degrees Celsius to about 800 degrees Celsius. In this step, the talc powder may be heated for about 1 minute to about 5 minutes.

After the preheating step, the talc powder is sintered in the oven at a temperature of about 1,000 degrees Celsius to about 1,200 degrees Celsius. The talc powder may be sintered for about 15 minutes to about 60 minutes.

After the sintering step, the talc powder is annealed. It is worth noting that the talc powder may be annealed in the oven instead of removing the talc powder from the oven. The annealing may be achieved by simply turning the oven off and allowing the oven to cool until room temperature and atmospheric pressure are achieved. In some embodiments, the talc powder may be annealed for about 7 hours to about 9 hours (e.g., 8 hours).

Talc powder that is prepared in accordance with the method described herein has a unique structure, as evidenced by the pattern of X-ray diffraction peaks observed in comparison to conventionally prepared talc powders. In some embodiments, talc powder that is prepared in accordance with the method described herein includes a first X-ray diffraction peak from about 29° to about 30° having a first intensity, and a second X-ray diffraction peak from about 25° to about 27° having a second intensity, wherein the first intensity is at least about 1% to about 80% greater than the second intensity. This is described in further detail in the Examples, infra. Some examples of X-ray diffraction techniques that may be used to analyze the structure of thermally processed talc powder prepared as described herein may include, without limitation, single-crystal X-ray diffraction, X-ray powder diffraction, thin film diffraction and grazing incidence X-ray diffraction, high-resolution X-ray diffraction, X-ray pole figure analysis, and X-ray rocking curve analysis.

In some embodiments, the hardness of the talc powder produced as described herein on the Mohs scale is about 5 to about 6, but less than 6. By comparison, the hardness of conventionally produced talc powder is typically greater than 6. A copper clad laminate which includes the talc powder produced as described herein is easier to process than conventionally produced talc powder. For example, talc powder produced as described herein may extend the operating life of a drill pin for drilling holes on the copper clad laminate in comparison with a conventionally produce material. In addition, undesired mechanical fractures of the copper clad laminate due to press molding may be prevented.

A thermally processed talc powder prepared as described herein may be incorporated into an epoxy resin blend for use in production of a copper clad laminate for a printed circuit board. The ratios of the epoxy compound, the crosslinking agent, the catalyst and the filler in such a resin may vary, depending on the applications of the epoxy resin blend. In some embodiments, the epoxy compound may be about 100 parts by weight, the crosslinking agent may be about 1 part by weight to about 60 parts by weight, the catalyst may be about 0.01 parts by weight to about 1 part by weight, and the filler may be about 1 part by weight to about 80 parts by weight. The epoxy resin blend may further include a solvent (e.g., dimethylformamide, methyl ethyl ketone) which may be about 20 parts by weight to about 200 parts by weight. In some embodiments, the filler may be about 40 parts by weight.

In some embodiments, the epoxy resin blend, including a thermally processed talc powder prepared as described herein, may be used for preparing a prepreg. A “prepreg” is a pre-impregnated composite fiber, which may be included in a copper clad laminate for use in a printed circuit board. A prepreg may include a fibrous material and a resin blend adhered on the fibrous material. A copper clad laminate may include a prepreg sandwiched between two copper sheets. A fibrous material may be immersed in and impregnated with the epoxy resin blend. The fibrous material may include, without limitation, glass cloth and matting, paper, asbestos paper, mica flakes, cotton bats, duck muslin, canvas and synthetic fabric such as nylons and polyethylene terephthalate, and/or woven/non-woven fiberglass fabrics. The impregnated fibrous material may be heated at a temperature of about 150 degrees Celsius to about 300 degrees Celsius for about 3 minutes to 7 minutes in an oven. In some embodiments, the impregnated material is pulled by several rollers into an oven. The fibrous material and the epoxy resin blend forms a prepreg after being heated by the oven.

In some embodiments, the prepreg may be used for preparing a copper clad laminate. A prepreg may be stacked between two copper sheets. Then, one or more sheets of the prepreg, sandwiched between the copper sheets, may be interposed between two stainless steel plates. The resulting assembly may be press-molded at a temperature of about 140 degrees Celsius to about 210 degrees Celsius at a pressure of about 8 kg/cm² to about 15 kg/cm² for about 40 minutes to about 100 minutes to prepare a copper-clad laminate.

In some embodiments, talc powder in a prepreg may be retrieved by putting the prepreg in an oven heated to a relatively high temperature (e.g., 625 degrees Celsius) for a period of time (e.g., 1 hour) sufficient to decompose and vaporize the organic substances (e.g., epoxy compound, catalyst, crosslinking agent) included in the prepreg. The organic substances may be vaporized and removed, with only the talc powder and the fibrous material remaining. The talc powder may be removed from the fibrous material with a blade. Talc powder in a copper clad laminate may be retrieved based on a similar approach.

### EXAMPLES

A first thermally processed talc powder was prepared in accordance with the method set forth above. About 50 percent of the first thermally processed talc powder had particle diameters of about 0.5 μm to about 50 μm. The first thermally processed talc powder was heated in an oven at a temperature of about 700 degrees Celsius for about 4 minutes, sintered in the oven at a temperature about 1,050 degrees Celsius for about 60 minutes, and annealed in the oven from about 1,000 degrees Celsius to room temperature and atmospheric pressure.

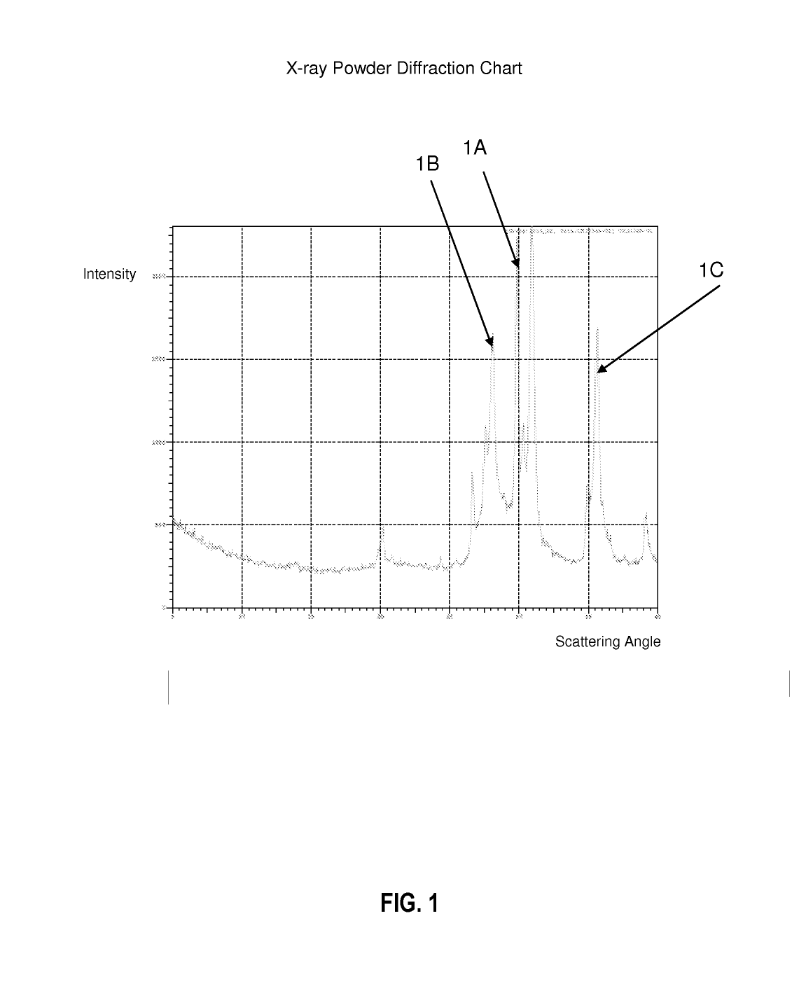

FIG. 1 is an X-ray powder diffraction (XRD) chart of the first thermally processed talc powder, which was sintered at a temperature about 1,050 degrees Celsius. The X-axis of the chart refers to the scattering angle, and the Y-axis of the chart refers to the intensity. FIG. 1 shows a first X-ray diffraction peak 1A from about 29° to about 30°, a second X-ray diffraction peak 1B from about 25° to about 27°, and a third X-ray diffraction peak 1C from about 35° to about 38°. The first diffraction peak 1A and the second diffraction peak 1B have a first intensity and a second intensity, respectively. The first intensity (e.g., about 2,200 as shown in FIG. 1) is at least about 30% greater than the second intensity (e.g., about 1,650 as shown in FIG. 1).

A second thermally processed talc powder was prepared in accordance with the method set forth above. About 50 percent of the second thermally processed talc powder had particle diameters of about 0.5 μm to about 50 μm. The second thermally processed talc powder was heated in an oven at a temperature of about 700 degrees Celsius for about 4 minutes, sintered in the oven at a temperature about 1,100 degrees Celsius for about 60 minutes, and annealed in the oven from about 1,100 degrees Celsius to room temperature and atmospheric pressure.

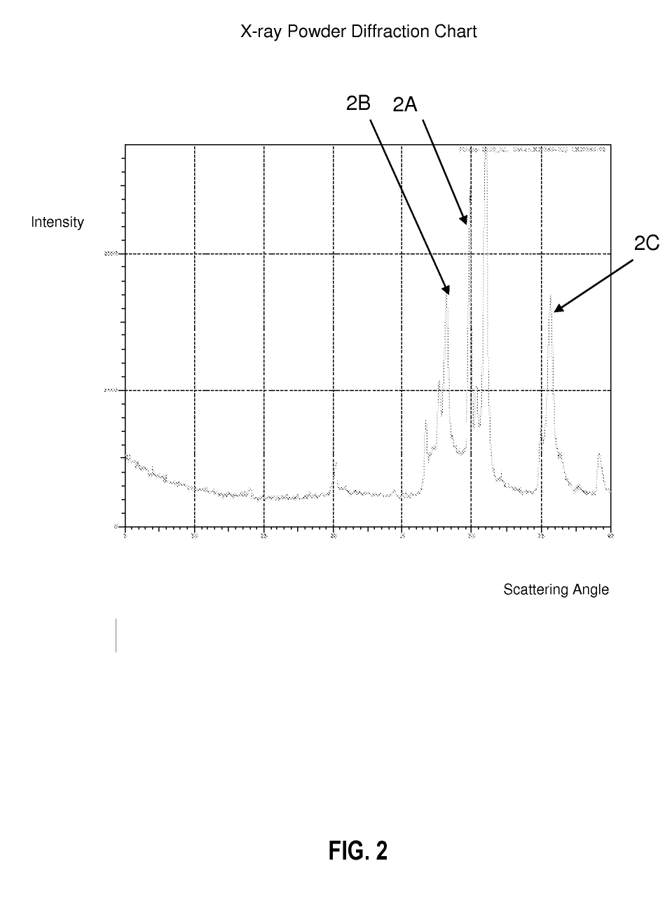

FIG. 2 is an XRD chart of the second thermally processed talc powder, which was been sintered at a temperature about 1,100 degrees Celsius. The X-axis of the chart refers to the scattering angle, and the Y-axis of the chart refers to the intensity. FIG. 2 shows a first X-ray diffraction peak 2A from about 29° to about 30°, a second X-ray diffraction peak 2B from about 25° to about 27°, and a third X-ray diffraction peak 2C from about 35° to about 37°. The first diffraction peak 2A and the second diffraction peak 2B have a first intensity and a second intensity, respectively. The first intensity (e.g., about 2,600 as shown in FIG. 2) is at least about 40% greater than the second intensity (e.g., about 1,800 as shown in FIG. 2).

### Comparative Examples

A third thermally processed talc powder was prepared. About 50 percent of the third thermally processed talc powder had particle diameters of about 0.5 μm to about 50 μm. The third thermally processed talc powder was heated in the oven at a temperature about 1,100 degrees Celsius for about 4 hours, and then cooled by removing the third thermally processed talc powder in an environment of room temperature and atmospheric pressure.

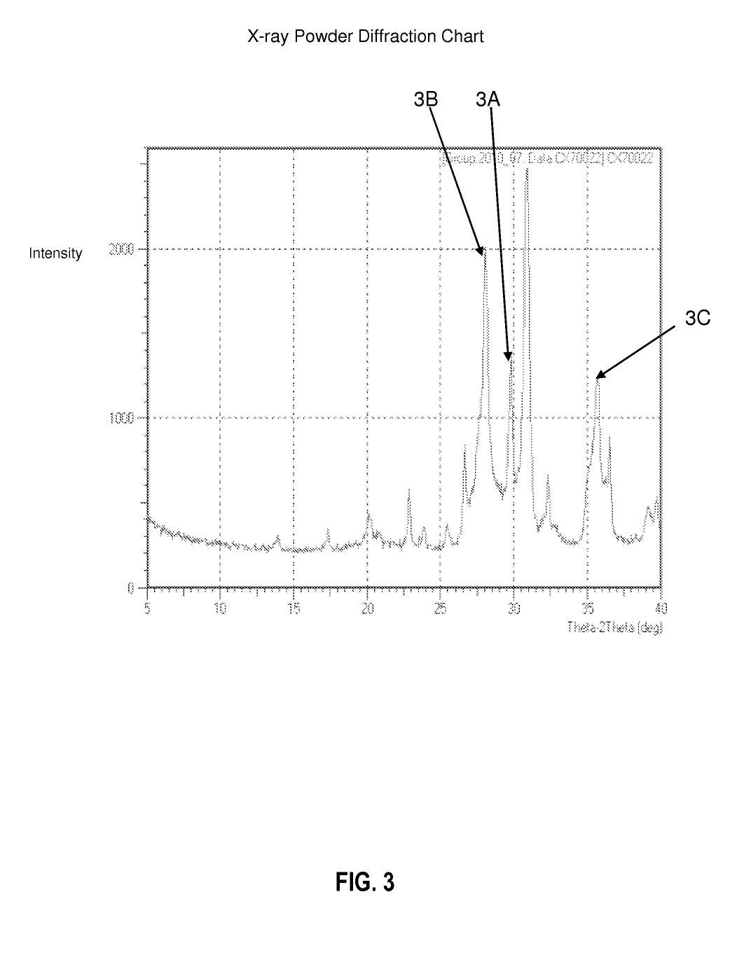

FIG. 3 is an XRD chart of the third thermally processed talc powder. The X-axis of the chart refers to the scattering angle, and the Y-axis of the chart refers to the intensity. FIG. 3 shows a first X-ray diffraction peak 3A from about 29° to about 30°, a second X-ray diffraction peak 3B from about 24° to about 28°, and a third X-ray diffraction peak 3C from about 35° to about 37°. The first diffraction peak 3A and the second diffraction peak 3B have a first intensity and a second intensity, respectively. The first intensity is less than the second intensity.

A fourth thermally processed talc powder was prepared. About 50 percent of the fourth thermally processed talc powder had particle diameters of about 0.5 μm to about 50 μm. The fourth thermally processed talc powder was heated in the oven at a temperature about 1,200 degrees Celsius for about 4 hours, and then cooled by removing the fourth thermally processed talc powder in an environment of room temperature and atmospheric pressure.

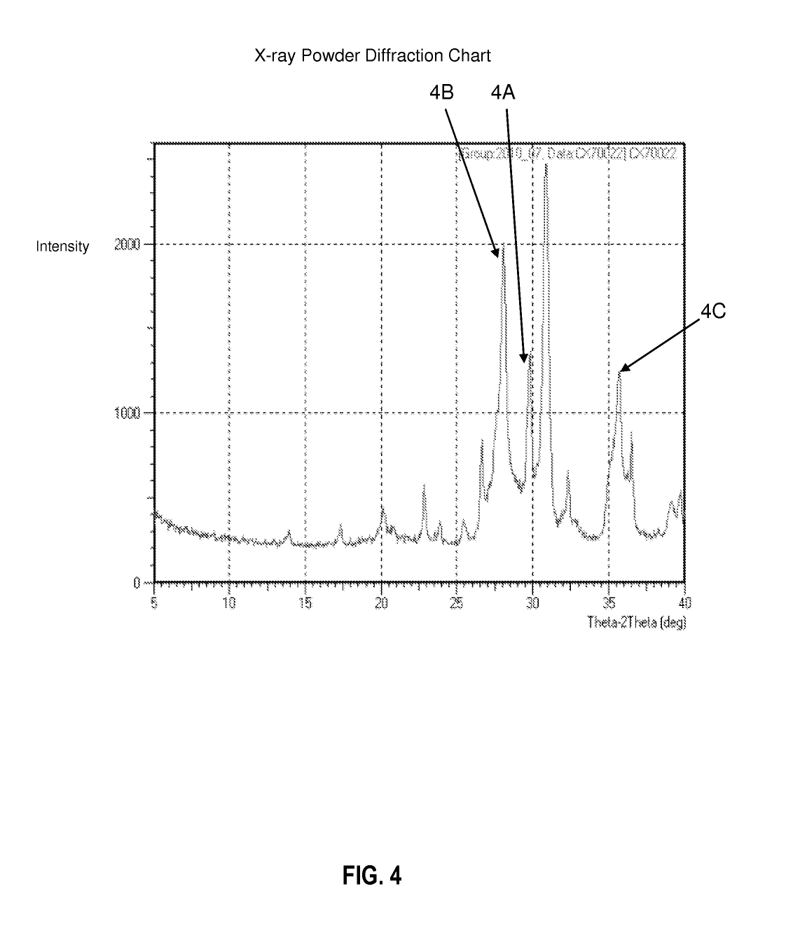

FIG. 4 is an XRD chart of the fourth thermally processed talc powder. The X-axis of the chart refers to the scattering angle, and the Y-axis of the chart refers to the intensity. FIG. 4 shows a first X-ray diffraction peak 4A from about 29° to about 30°, a second X-ray diffraction peak 4B from about 24° to about 28°, and a third X-ray diffraction peak 4C from about 35° to about 37°. The first diffraction peak 4A and the second diffraction peak 4B have a first intensity and a second intensity, respectively. The first intensity is less than the second intensity.

Although the foregoing invention has been described in some detail by way of illustration and examples for purposes of clarity of understanding, it will be apparent to those skilled in the art that certain changes and modifications may be practiced without departing from the spirit and scope of the invention. Therefore, the description should not be construed as limiting the scope of the invention.

All publications, patents, and patent applications cited herein are hereby incorporated by reference in their entireties for all purposes and to the same extent as if each individual publication, patent, or patent application were specifically and individually indicated to be so incorporated by reference.

We claim:

1. A sintered talc powder comprising a first X-ray diffraction peak from about 29° to about 30° having a first intensity, and a second X-ray diffraction peak from about 25° to about 27° having a second intensity, wherein the first intensity is greater than the second intensity.

2. The sintered talc powder of claim 1, further comprising a third X-ray diffraction peak from about 35° to about 38°.

3. The sintered talc powder of claim 1, wherein the particle diameter of the powder is less than about 200 μm.

4. The sintered talc powder of claim 3, wherein the particle diameter of about 50 percent of the powder is within a range of about 0.5 μm to about 50 μm.

5. The sintered talc powder of claim 1, comprising a hardness less than 6 on the Mohs scale.

6. The sintered talc powder of claim 5, wherein the hardness on the Mohs scale is about 5 to about 6.

7. The sintered talc powder of claim 1, wherein the sintered talc has been heated at a temperature of about 600° C. to about 800° C. prior to sintering.

8. The sintered talc powder of claim 1, wherein the sintered talc has been sintered at a temperature of about 1,000° C. to about 1,200° C.

9. A composition comprising:
a fibrous material coated with a resin blend comprising the sintered talc powder of claim 1.

10. The composition of claim 9, wherein the resin blend comprises about 100 parts by weight of an epoxy compound, and about 1 to 80 parts by weight of the sintered talc.

11. The composition of claim 10, wherein the sintered talc is about 40 parts by weight in the resin blend.

12. A non-conductive substrate comprising a first metal sheet and a fibrous material which includes the sintered talc of claim 1.

13. The non-conductive substrate of claim 12, further comprising a second metal sheet, wherein the fibrous material is arranged between the first metal sheet and the second metal sheet.

14. A printed circuit board comprising the non-conductive substrate of claim 13.

15. A method for making a talc powder, comprising:
preheating the talc powder;
sintering the talc powder, after the preheating and; and
annealing the talc powder, after the sintering.

16. The method according to claim 15, wherein said preheating, sintering, and annealing steps are performed in an oven.

17. The method of claim 15, wherein in the preheating step, the talc powder is heated at a temperature of about 600 degrees Celsius to about 800 degrees Celsius for about 1 minute to about 5 minutes.

18. The method of claim 15, wherein in the sintering step, the talc powder is sintered at a temperature of about 1,000 degrees Celsius to about 1,200 degrees Celsius for about 15 minutes to about 60 minutes.

19. The method of claim 15, wherein in the annealing step, the oven is turned off and cooled from the temperature at which the talc powder is sintered to room temperature and atmospheric pressure and the talc powder is kept in the oven for about 8 hours.
